(19) United States
(12) Patent Application Publication
(10) Pub. No.: US 2023/0187004 A1
(43) Pub. Date: Jun. 15, 2023

(54) FUSE BLOWING METHOD AND APPARATUS FOR MEMORY, STORAGE MEDIUM, AND ELECTRONIC DEVICE

(71) Applicant: CHANGXIN MEMORY TECHNOLOGIES, INC., Hefei (CN)

(72) Inventors: Jianbin LIU, Hefei (CN); Maosong MA, Hefei (CN); Jin QIAN, Hefei (CN)

(21) Appl. No.: 17/857,038

(22) Filed: Jul. 4, 2022

Related U.S. Application Data
(63) Continuation of application No. PCT/CN2022/089342, filed on Apr. 26, 2022.

(30) Foreign Application Priority Data
Dec. 15, 2021 (CN) 202111536723.X

(51) Int. Cl. G11C 29/02; G11C 29/50

(52) U.S. Cl. CPC G11C 29/027; G11C 29/50004; G11C 2029/5004

(57) ABSTRACT

Provided are a fuse blowing method and apparatus for a memory, a storage medium, and an electronic device. The method includes: controlling a memory to enter a test mode, and reducing an internal clock frequency of the memory (S210); starting a fuse blowing load mode, and controlling the memory to enter a fuse blowing mode (S220); enabling internal precharge of the memory, and writing a location of a fuse to be blown into a fuse blowing location register (S230); starting a fuse blowing process of the memory, and disabling the internal precharge after preset time (S240); and controlling the memory to exit the fuse blowing mode and the test mode successively (S250).

### CROSS-REFERENCE TO RELATED APPLICATION

The present disclosure is a continuation of PCT/CN2022/089342, filed on Apr. 26, 2022, which claims priority to Chinese Patent Application No. 202111536723.X, titled “FUSE BLOWING METHOD AND APPARATUS FOR MEMORY, STORAGE MEDIUM, AND ELECTRONIC DEVICE” and filed on Dec. 15, 2021, the entire contents of which are incorporated herein by reference.

### TECHNICAL FIELD

The present disclosure relates to the field of data processing technology, and more particularly, to a fuse blowing method and apparatus for a memory, a storage medium, and an electronic device.

### BACKGROUND

With the rapid development of computer technologies, integrated circuit (IC) chips play an increasingly important role in people's production and life. However, it is unavoidable to cause a problem of failure of chips in the process of development, production and use. Generally, a backup circuit may be employed to repair failure locations of the chips.

In the prior art, generally chip repair is implemented by means of high-end IC automatic test equipment (ATE). The ATE generally has relatively powerful functions.

However, the ATE is expensive in fabrication cost and complicated in operation, resulting in higher chip repair costs.

### SUMMARY

According to an aspect of the present disclosure, there is provided a fuse blowing method for a memory. The method includes: providing a programmable device; and executing the memory by means of the programmable device by: controlling the memory to enter a test mode, and reducing an internal clock frequency of the memory; starting a fuse blowing load mode, and controlling the memory to enter a fuse blowing mode; enabling internal precharge of the memory, and writing a location of a fuse to be blown into a fuse blowing location register; starting a fuse blowing process of the memory, and disabling the internal precharge after preset time; and controlling the memory to exit the fuse blowing mode and the test mode successively.

According to an aspect of the present disclosure, there is provided a fuse blowing apparatus for a memory. The apparatus includes: a programmable device, which includes: a first control circuit, a second control circuit, a third control circuit, a fourth control circuit, and a fifth control circuit. The first control circuit is configured to control the memory to enter a test mode, and reduce an internal clock frequency of the memory. The second control circuit is configured to start a fuse blowing load mode, and control the memory to enter a fuse blowing mode. The third control circuit is configured to enable internal precharge of the memory, and write a location of a fuse to be blown into a fuse blowing location register. The fourth control circuit is configured to start a fuse blowing process of the memory, and disable the internal precharge after preset time. The fifth control circuit is configured to control the memory to exit the fuse blowing mode and the test mode successively.

According to an aspect of the present disclosure, there is provided a computer-readable storage medium storing a computer program thereon, the computer program is executable by a processor, whereby the fuse blowing method for a memory is implemented.

According to an aspect of the present disclosure, there is provided an electronic device, which includes: a processor; and a memory configured to store one or more programs that, when executed by the processor, cause the processor to implement the fuse blowing method for a memory.

It is to be understood that the above general description and the detailed description below are merely exemplary and explanatory, and do not limit the present disclosure.

### BRIEF DESCRIPTION OF THE DRAWINGS

The accompanying drawings herein are incorporated in and constitute a part of this specification, illustrate embodiments conforming to the present disclosure and, together with the specification, serve to explain the principles of the present disclosure. Apparently, the accompanying drawings in the following description show merely some embodiments of the present disclosure, and persons of ordinary skill in the art may still derive other drawings from these accompanying drawings without creative efforts.

FIG. 1 schematically shows a schematic structural diagram of a chip according to an exemplary embodiment of the present disclosure;

FIG. 2 schematically shows a schematic flow diagram of a fuse blowing method for a memory according to an exemplary embodiment of the present disclosure;

FIG. 3 schematically shows a schematic diagram of a connection relationship between a programmable device and a memory according to an exemplary embodiment of the present disclosure;

FIG. 4 schematically shows a block diagram of a fuse blowing apparatus for a memory according to an exemplary embodiment of the present disclosure; and

FIG. 5 schematically shows a schematic block diagram of an electronic device according to an exemplary embodiment of the present disclosure.

### DETAILED DESCRIPTION

The exemplary embodiments will now be described more fully with reference to the accompanying drawings. However, the exemplary embodiments can be implemented in a variety of forms and should not be construed as being limited to the embodiments set forth herein. Rather, these embodiments are provided such that the present disclosure will be thorough and complete and will fully convey the concepts of exemplary embodiments to those skilled in the art. Throughout the drawings, similar reference signs indicate the same or similar structures, and their detailed description will be omitted.

Although this specification employs relativity terms such as “above” and “below” to describe a relative relation between one component and another component of icons, these terms are merely for convenience of this specification, for example, the directions of the examples in the accompanying drawings. It is to be understood that when the apparatus of the icon are turned upside down, components described as “above” will become components described as “below”. Other relative terms such as “high”, “low”, “top”, “bottom”, “left”, “right” and so on also have similar meanings. When a certain structure is “above” other structures, it likely means that a certain structure is integrally formed on other structures, or a certain structure is “directly” arranged on other structures, or a certain structure is “indirectly” arranged on other structures by means of another structure.

The terms “one”, “a” and “the” are intended to mean that there exists one or more elements/constituent parts/etc. The terms “comprising” and “having” are intended to be inclusive and mean that there may be additional elements/constituent parts/etc. other than the listed elements/constituent parts/etc.

One chip generally includes a plurality of memory cells. For example, one typical dynamic random access memory (DRAM) chip has as many as 64 million memory cells, which may be arranged in a main array in rows and columns for addressing by means of word lines and bit lines.

During fabrication of the typical DRAM chip, a million or even millions of memory cells in the main array may likely have defects, i.e., so-called failure locations. To improve yield of the chip, redundancy circuits are generally fabricated on the chip. These redundancy circuits may replace the word lines or bit lines where defective failure locations are positioned, thereby bypassing these defective failure locations, such that a memory circuit can run normally.

Generally, after failure locations are generated during development, production and use of the chip, the failure locations may be detected in a test stage. When the failure locations are detected, the backup circuits in the chip may be allocated by means of fuse blowing to repair the failure locations.

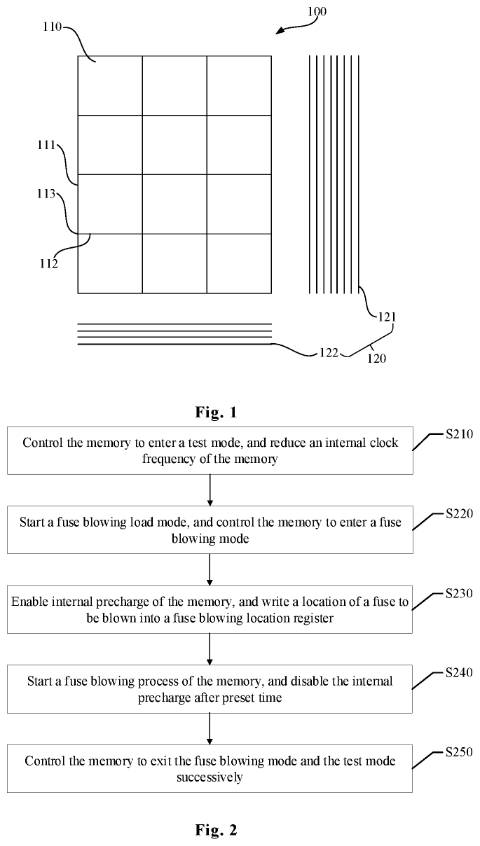

Referring to FIG. 1, a schematic structural diagram of a chip according to an exemplary embodiment of the present disclosure is shown. A chip 100 generally includes a normal cell area 110 and a redundancy cell area 120. The normal cell area 110 includes more memory cells, and the normal cell area 110 includes two types of orthogonal lines: word lines 111 and bit lines 112, where the word lines 111 are column lines, and the bit lines 112 are row lines. Meanwhile, in addition to the normal cell area 110, the chip 100 is also provided with a redundancy cell area 120 including redundancy cells. The redundancy cell area 120 includes two types of orthogonal straight lines: a redundancy word-line (RWL) 121 and a redundancy bit-line (RBL) 122, where the RWL 121 is a column line configured to repair the failure locations on the word lines 111; and the redundancy bit-line 122 is a row line configured to repair the failure locations on the bit lines 112.

Referring to FIG. 2, an exemplary embodiment of the present disclosure provides a fuse blowing method for a memory, where the programmable device may be a field-programmable gate array (FPGA), or a complex programmable logic device (CPLD), etc. By means of the programmable device, memories such as DRAM may be controlled to perform a fuse blowing operations, thereby achieving the repair of the failure locations.

FIG. 2 schematically shows a schematic flow diagram of a fuse blowing method for a memory according to some embodiments of the present disclosure. Referring to FIG. 2, the fuse blowing method for a memory may include: providing a programmable device, and performing following steps on the memory by means of the programmable device:

Step S210: controlling the memory to enter a test mode, and reducing an internal clock frequency of the memory;

Step S220: starting a fuse blowing load mode, and controlling the memory to enter a fuse blowing mode;

Step S230: enabling internal precharge of the memory, and writing a location of a fuse to be blown into a fuse blowing location register;

Step S240: starting a fuse blowing process of the memory, and disabling the internal precharge after preset time; and

Step S250: controlling the memory to exit the fuse blowing mode and the test mode successively.

According to the fuse blowing method for a memory in this exemplary embodiment, first the memory is controlled to enter the test mode by means of the programmable device, and then the internal clock frequency of the memory is reduced. Next, the fuse blowing load mode is started to control the memory to enter the fuse blowing mode. After the internal precharge of the memory is enabled, the location of the fuse to be blown is written into the fuse blowing location register. Next, the fuse blowing process of the memory is started, and the internal precharge is disabled after preset time. After a fuse blowing operation is achieved, the memory is controlled to exit the fuse blowing mode and the test mode successively. In this way, the fuse blowing operation is implemented by controlling the memory by means of the programmable device, thereby completing the repair of the failure locations.

Next, the fuse blowing method for a memory in this exemplary embodiment will be further described.

In some exemplary embodiments of the present disclosure, as shown in FIG. 1, the failure location 113 is a location in the normal cell area 110, and the failure location 113 is on the word line 111 or the bit line 112. Therefore, the failure location 113 may be repaired by replacing the word line 111 with the redundancy word-line 121, or the failure location 113 may be repaired by replacing the bit line 112 with the redundancy bit-line 122, and the replacement process may be achieved by means of the fuse blowing operation.

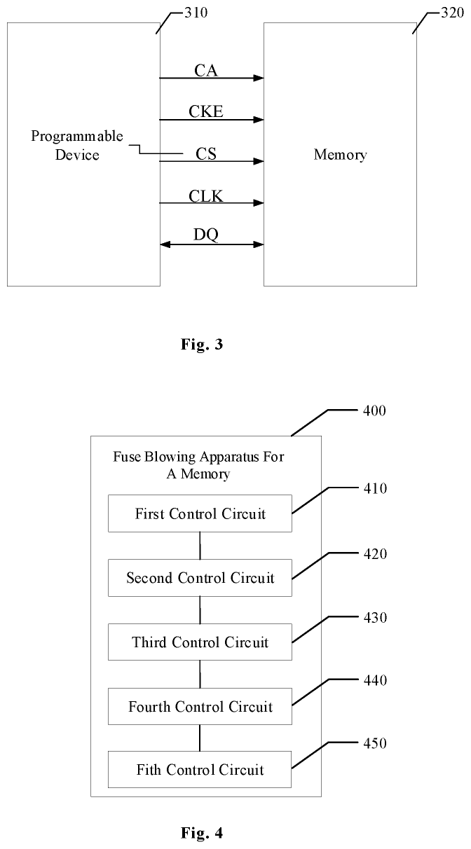

In an exemplary embodiment of the present disclosure, before the memory is controlled to perform the fuse blowing operation by means of the programmable device, the programmable device needs to be connected to the memory. Taking a memory DRAM as an example, as shown in FIG. 3, a programmable device 310 may be connected to a CA pin, a CKE pin, a CS pin, a CLK pin and a DQ pin of a memory 320. As a command/address input signal, the CA may be used as an address line or as a command code, serving as a part of the command code. The CKE is a clock enable signal, and when the CKE signal is a high level, an internal clock signal is activated, such that a device input buffer and an output drive unit are started. The CS is a chip select signal, the CLK represents a clock signal, and the DQ is an input\output signal, which refers to a bidirectional data bus for data input/output.

The programmable device may complete the fuse blowing process of the memory by writing corresponding instructions or data into the memory. Each of operation steps will be described in detail below.

In Step I, the programmable device 310 is configured to control the memory 320 to enter the test mode.

In an exemplary embodiment of the present disclosure, the controlling the memory 320 to enter a test mode may include: consecutively writing three different first preset data into a test mode register in sequence, to control the memory 320 to enter the test mode. The test mode register is configured to temporarily store relevant instructions and signals of the test mode, such that the memory 320 may enter the test mode according to the relevant instructions and signals.

In some embodiments, the consecutively writing three different first preset data into a test mode register in sequence may include: sending address data of the test mode register and the three different first preset data to the memory 320 by means of a first mode register write (MRW) command.

In practical applications, the address data of the test mode register may be determined according to concrete conditions of the memory 320, and the three different first preset data may be preset to control the memory 320 to enter the test mode.

In an exemplary implementation of the present disclosure, taking an example where the address data of the test mode register is MA=0x9 and one of the three different first preset data is OP=0x56, the programmable device 310 may send MRW(MA=0x9, OP=0x56) to the memory by means of the MRW command to complete related operations.

The hexadecimal 0x9 is converted into binary 001001, which corresponds to MA[5:0]; and hexadecimal 0x56 is converted into binary 01010110, which corresponds to OP[7:0]. These two data may be sent by triggering by means of four rising edges of the CLK clock, as shown in a truth table shown in Table 1.

TABLE 1

| Truth | | | | | | | | | |
|---|---|---|---|---|---|---|---|---|---|
| Table | CLK | CKE | CS | CA0 | CA1 | CA2 | CA3 | CA4 | CA5 |
| MRW | R1 | 1 | 1 | 0 | 1 | 1 | 0 | 0 | OP7 |
| | R2 | 1 | 0 | MA0 | MA1 | MA2 | MA3 | MA4 | MA5 |
| | R3 | 1 | 1 | 0 | 1 | 1 | 0 | 1 | OP6 |
| | R4 | 1 | 0 | OP0 | OP1 | OP2 | OP3 | OP4 | OP5 |

R1 represents the first rising edge of CLK, R2 represents the second rising edge of CLK, R3 represents the third rising edge of CLK, and R4 represents the fourth rising edge of CLK.

As can be seen from Table 1, MA=0x9 is transmitted by MA5-MA0 in the MRW instruction, and OP=0x56 is transmitted by OP7-OP0 in the MRW instruction. Furthermore, on the first rising edge R1 of the CLK, the CKE pin is “1”, the CS pin is “1”, and the CA[5:0] pin is “000110”; on the second rising edge R2 of the CLK, the CKE pin is “1”, the CS pin is “0”, and the CA[5:0] pin is “001001”; on the third rising edge R3 of the CLK, the CKE pin is “1”, the CS pin is “1”, and the CA[5:0] pin is “110110”; and on the fourth rising edge R4 of the CLK, the CKE pin is “1”, the CS pin is “0”, and the CA[5:0] pin is “010110”.

It should be noted that the instruction transmission manner in Table 1 is only an example, and does not constitute limitation on the embodiments of the present disclosure. In practical applications, the address data of the test mode register and the three different first preset data may be set according to actual conditions, which are not specially limited in the exemplary embodiments of the present disclosure.

In addition, in the process of consecutively writing three different first preset data into a test mode register in sequence, the address data of the test mode register and first first preset data may be sent to the memory 320 by means of the MRW instruction. After an interval of first preset time, the address data of the test mode register and second first preset data are sent to the memory 320 by means of the MRW instruction. After an interval of second preset time, the address data of the test mode register and third first preset data are sent to the memory 320 by means of the MRW instruction.

In practical applications, the first preset time and the second preset time may be determined according to concrete conditions. For example, both the first preset time and the second preset time are 10 μs, etc. However, values of the first preset time and values of the second preset time are not specially limited in the exemplary embodiments of the present disclosure.

After the programmable device 310 controls the memory 320 to enter the test mode in Step I, in Step II, the programmable device 310 sends an instruction to the memory 320 to reduce the internal clock frequency of the memory 320.

In an exemplary embodiment of the present disclosure, the reducing an internal clock frequency of the memory 320 may include: setting a first preset bit of a clock frequency register to 1 and then to 0 by means of the first MRW command, to reduce the internal clock frequency.

Here, the setting a first preset bit of a clock frequency register to 1 and then to 0 may also be implemented by means of OP data. For example, taking a hexadecimal number as an example, data OP=0x4 may be first written into the clock frequency register, and then data OP=0x0 is written into the clock frequency register, to achieve modification of the first preset bit of the clock frequency register. That is, the address data of the clock frequency register and the above two OP data may be sent at intervals to the memory 320 by means of the first MRW command, to achieve the modification of the first preset bit. Reference may be made to Table 1 for a manner of writing the MRW command, which is not to be repeated here.

It should be noted that the address data of the clock frequency register is also determined according to concrete conditions of the memory, which is not limited in the exemplary embodiments of the present disclosure. In addition, the first preset bit of the clock frequency register is a bit pre-agreed in the memory 320 to reduce the internal clock frequency, and the concrete location of the first preset bit may be adjusted according to actual situations. For example, the first preset bit may be bit 3 of the clock frequency register. That is, the bit 3 of the clock frequency register may be first set to 1 and then set to 0, to reduce the internal clock frequency of the memory 320.

In this exemplary embodiment of the present disclosure, by reducing the internal clock frequency of the memory 320, an objective of delaying the fuse blowing is achieved, such that sufficient processing time may be reserved for the fuse blowing process.

After the programmable device 310 reduces the internal clock frequency of the memory 320 in Step II, after an interval of preset time, in Step III, the fuse blowing load mode is started.

In an exemplary embodiment of the present disclosure, the starting a fuse blowing load mode may include: consecutively writing two different second preset data into a fuse blowing load register, to control the memory 320 to start the fuse blowing load mode. After the fuse blowing load mode is started, the fuse blowing mode may be loaded in the memory 320 to facilitate subsequent fuse blowing operations.

In some embodiments, the consecutively writing two different second preset data into a fuse blowing load register may include: sending address data of the fuse blowing load register and the two different second preset data to the memory 320 by means of the first MRW command. In some embodiments, the address data of the fuse blowing load register and first second preset data may be first sent to the memory 320 by means of the MRW instruction; and after an interval of preset time, the address data of the fuse blowing load register and second second preset data may be sent to the memory 320 by means of the MRW instruction, where length of the preset time is not limited in the exemplary embodiments of the present disclosure.

In practical applications, the address data of the fuse blowing load register may be determined according to concrete conditions of the memory, and reference may be made to Table 1 for a manner of writing the address data of the fuse blowing load register and the two different second preset data in the MRW instruction, which is not to be repeated here.

After the programmable device 310 controls the memory 320 to start the fuse blowing load mode in Step III, after an interval of preset time, in Step IV, the memory 320 is controlled to enter the fuse blowing mode.

In this exemplary embodiment of the present disclosure, the controlling the memory 320 to enter a fuse blowing mode may include: writing third preset data into a first fuse blowing register, to control the memory 320 to enter the fuse blowing mode.

In some embodiments, the writing third preset data into a first fuse blowing register may include: sending the third preset data to the memory 320 by means of a second mode register write (TMRW) command. The TMRW command may be a self-defined command. For example, in the DRAM, an RFU (Reserved For Use) command may be changed to the TMRW command, as shown in Table 2.

TABLE 2

| Truth | | | | | | | | | |
|---|---|---|---|---|---|---|---|---|---|
| Table | CLK | CKE | CS | CA0 | CA1 | CA2 | CA3 | CA4 | CA5 |
| TMRW | R1 | 1 | 1 | 0 | 1 | 0 | 1 | 1 | MA8 |
| | R2 | 1 | 0 | MA0 | MA1 | MA2 | MA3 | MA4 | MA5 |
| | R3 | 1 | 1 | 0 | 1 | 0 | 1 | 1 | MA7 |
| | R4 | 1 | 0 | OP0 | OP1 | OP2 | OP3 | OP4 | MA6 |

The third preset data may be determined according to actual situations of the DRAM, which is not limited in the exemplary embodiments of the present disclosure. Moreover, reference may be made to the manner of writing data by means of the MRW command for a manner of writing the third preset data by means of the TMRW command, which is not to be repeated here.

After the programmable device 310 controls the memory 320 to enter the fuse blowing mode in Step IV, after an interval of preset time, in Step V, the memory 320 is controlled to enable the internal precharge.

In this exemplary embodiment of the present disclosure, the enabling internal precharge of the memory 320 may include: setting a second preset bit of a second fuse blowing register to 0 and then to 1 by means of a second mode register write (TMRW) command, to enable the internal precharge.

Here, the setting a second preset bit of a second fuse blowing register to 0 and then to 1 may be implemented by means of OP data in the TMRW command. For example, taking a hexadecimal number as an example, data OP=0x0 may be first written into the second fuse blowing register, and then data OP=0x2 is written, to achieve modification of the second preset bit of the second fuse blowing register. That is, the address data of the second fuse blowing register and the above two OP data may be sent at intervals to the memory 320 by means of the TMRW command, to achieve the modification of the second preset bit. Reference may be made to the MRW command for a manner of writing data by means of the TMRW command, which is not to be repeated here.

In practical applications, the second preset bit of the second fuse blowing register is a bit pre-agreed in the memory 320 to enable the internal precharge, and a concrete location of the second preset bit may be adjusted according to actual situations. For example, the second preset bit may be bit 2 of the second fuse blowing register. That is, the bit 2 of the second fuse blowing register may be first set to 0 and then set to 1, to enable the internal precharge of the memory 320.

After the programmable device 310 controls the memory 320 to enable the internal precharge in Step V, after an interval of preset time, in Step VI, the memory 320 is controlled to write the location of the fuse to be blown into the fuse blowing location register.

In an exemplary embodiment of the present disclosure, the writing a location of a fuse to be blown into a fuse blowing location register may include: writing a coordinate value corresponding to the location of the fuse to be blown into the fuse blowing location register by means of the TMRW command.

The location of the fuse to be blown is detected in a test stage of the memory. The coordinate value corresponding to the location of the fuse to be blown is written into the fuse blowing location register, and the coordinate value corresponding to the location of the fuse to be blown and the address data of the fuse blowing location register may also sent to the memory 320 by means of the TMRW command, where reference may be made to the above embodiments for a concrete sending manner, which is not to be repeated here.

After the programmable device 310 controls the memory 320 to write the location of the fuse to be blown into the fuse blowing location register in Step VI, after an interval of preset time, in Step VII, a fuse blowing process of the memory 320 may be started.

In this exemplary embodiment of the present disclosure, the starting a fuse blowing process of the memory 320 may include: setting all third preset bits of a fuse blowing start register to 1 and then to 0 by means of the TMRW command, to start the fuse blowing process.

In practical applications, the third preset bits of the fuse blowing start register may be determined according to actual situations. For example, the third preset bits may be bits 0 to 3 of the fuse blowing start register. No special limitation is imposed on the third preset bit in the exemplary embodiments of the present disclosure.

Reference may be made to the above-mentioned clock frequency register for the process of setting all third preset bits of a fuse blowing start register to 1 and then to 0, which is not to be repeated here.

After the fuse blowing process is started, it is required to wait for preset time to complete the fuse blowing. The preset time may be determined according to actual situations. For example, the preset time may be 3 ms, which is not limited in the exemplary embodiments of the present disclosure.

After the programmable device 310 starts the fuse blowing process of the memory 320 in Step VII, after an interval of preset time, in Step VIII, the internal precharge is disabled.

The disabling internal precharge may include: after the preset time such as 3 ms, writing 0 into the second fuse blowing register by means of the TMRW command, to disable the internal precharge.

In some embodiments, a manner of writing 0 into the second fuse blowing register may include: sending the address data of the second fuse blowing register and the data 0 to the memory 320 by means of the TMRW command. Reference may be made to the foregoing embodiments for a concrete sending manner, which is not to be repeated here.

After the programmable device 310 disables the internal precharge in Step VIII, this means that the fuse blowing operation of the memory 320 has been completed. After an interval of preset time, in Step IX, the memory 320 is controlled to exit the fuse blowing mode and the test mode successively.

In some embodiments, the controlling the memory 320 to exit the fuse blowing mode may include: writing 0 into the first fuse blowing register by means of the TMRW command, to control the memory 320 to exit the fuse blowing mode.

The controlling the memory 320 to exit the test mode may include: writing fourth preset data into the test mode register corresponding to Step I by means of the MRW command, to control the memory 320 to exit the test mode. A value of the fourth preset data may be set with reference to actual situations, which is not limited in the exemplary embodiments of the present disclosure.

Reference may be made to the process of writing the first preset data into the test mode register for a manner of writing the fourth preset data into the test mode register, which is not to be repeated here.

It should be noted that the register address data and the preset data of the memory 320 involved in the embodiments of the present disclosure may be determined according to actual situations of the memory 320, which is not limited in the exemplary embodiments of the present disclosure.

In the exemplary embodiments of the present disclosure, through the above Step I to Step IX, the programmable device may control the memory 320 to complete the fuse blowing process. Because memories such as DRAM have no high requirements on a working rate of the fuse blowing operations, the existing programmable devices such as FPGA or CPLD can meet the requirements, and costs of the fuse blowing operations can be reduced.

It is to be noted that steps of the method in the present disclosure are described in a particular order in the accompanying drawings. However, this does not require or imply to execute these steps necessarily according to the particular order, or this does not mean that the expected result cannot be implemented unless all the shown steps are executed. Additionally, some steps may be omitted, a plurality of steps may be combined into one step for execution, and/or one step may be decomposed into a plurality of steps for execution.

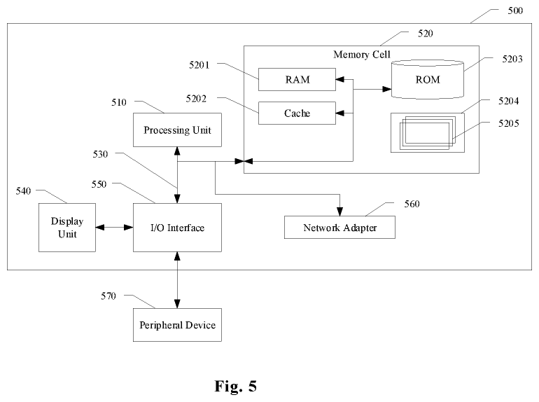

In addition, in this exemplary embodiment, there is also provided a fuse blowing apparatus for a memory. Referring to FIG. 4, the fuse blowing apparatus 400 for a memory may include a programmable device.

The programmable device may include:

a first control circuit 410, a second control circuit 420, a third control circuit 430, a fourth control circuit 440, and a fifth control circuit 450.

The first control circuit 410 may be configured to control the memory to enter a test mode, and reduce an internal clock frequency of the memory.

The second control circuit 420 may be configured to start a fuse blowing load mode, and control the memory to enter a fuse blowing mode.

The third control circuit 430 may be configured to enable internal precharge of the memory, and write a location of a fuse to be blown into a fuse blowing location register.

The fourth control circuit 440 may be configured to start a fuse blowing process of the memory, and disable the internal precharge after preset time.

The fifth control circuit 450 may be configured to control the memory to exit the fuse blowing mode and the test mode successively.

Concrete details of virtual circuits of each of the fuse blowing apparatuses 400 for a memory have been described in detail in the corresponding fuse blowing method for a memory, and thus are not to be repeated here.

It is to be noted that although a plurality of circuits or units of the fuse blowing apparatus for a memory have been mentioned in the above detailed description, this division is not mandatory. Actually, according to the embodiments of the present disclosure, features and functions of two or more circuits or units as described above may be embodied in one circuit or unit. Reversely, features and functions of one circuit or unit as described above may be further embodied in more circuits or units.

Moreover, the above accompanying drawings are merely illustrative description of processes included in the method according to the exemplary embodiments of the present disclosure and are not intended to limit the present disclosure. It is easy to understand that the processes shown in the above accompanying drawings do not indicate or limit time sequences of these processes. Furthermore, it is also easy to understand that these processes may be executed, for example, synchronously or asynchronously in a plurality of circuits.

In an exemplary embodiment of the present disclosure, there is further provided an electronic device capable of implementing the above method.

As will be appreciated by one skilled in the art, aspects of the present disclosure may be embodied as a system, method or program product. Accordingly, aspects of the present disclosure may take the form of an entirely hardware embodiment, an entirely software embodiment (including firmware, micro-code, etc.) or an embodiment combining software and hardware aspects that may all generally be referred to herein as a “circuit,” “circuit” or “system.”

The electronic device 500 according to this embodiment of the present disclosure is described below with reference to FIG. 5. The electronic device 500 as shown in FIG. 5 is merely an example, and no limitation should be imposed on functions or scope of use of the embodiment of the present disclosure.

As shown in FIG. 5, the electronic device 500 is shown in the form of a general-purpose computing device. Components of the electronic device 500 may include, but are not limited to: at least one processing unit 510, at least one memory cell 520, a bus 530 connecting different system components (including the memory cell 520 and the processing unit 510), and a display unit 540.

The memory cell 520 stores a program code, which may be executed by the processing unit 510, such that the processing unit 510 performs steps described in the “exemplary method” portions of this specification according to exemplary embodiments of the present disclosure. For example, the processing unit 510 may perform the Step I to Step IX.

The memory cell 520 may include readable media in the form of volatile memory cell, such as a random access memory (RAM) 5201 and/or a cache memory cell 5202. Furthermore, the memory cell 520 may further include a read-only memory (ROM) 5203.

The memory cell 520 may include a program/utility tool 5204 having a group of (at least one) program circuits 5205. The program circuits 5205 include, but are not limited to: an operating system, one or more applications, other program circuits and program data. Each or a certain combination of these examples may include implementation of network environment.

The bus 530 may represent one or more of a plurality of bus structures, including a memory bus or memory controller, a peripheral bus, an accelerated graphics port, a processing unit or a local bus using any bus structure among the plurality of bus structures.

The electronic device 500 may communicate with one or more peripheral devices 570 (such as keyboards, pointing devices, Bluetooth devices, etc.), and also may communicate with one or more devices allowing a user to interact with the electronic device 500, and/or may communicate with any device (for example, a router, a modem and so on) allowing the electronic device 500 to communicate with one or more other computing devices. This communication may be implemented by means of an input/output (I/O) interface 550. Moreover, the electronic device 500 also may communicate with one or more networks (for example, a local area network (LAN), a wide area network (WAN) and/or a public network such as the Internet) via a network adapter 560. As shown in FIG. 6, the network adapter 560 communicates with other circuits of the electronic device 500 through the bus 530. It should be understood that although not shown in the figures, other hardware and/or software circuits may be used in combination with the electronic device 500, including but not limited to: microcode, device drivers, redundancy processing units, external disk drive arrays, redundant arrays of independent disks (RAID) systems, tape drives and data backup and storage systems, etc.

With description of the above embodiments, it will be readily understood by those skilled in the art that the exemplary embodiments described herein may be implemented by software or may be implemented by means of software in combination with the necessary hardware. Thus, the technical solution according to the embodiments of the present disclosure may be embodied in the form of a software product which may be stored in a nonvolatile storage medium (which may be CD-ROM, USB flash disk, mobile hard disk and the like) or on network, including a number of instructions for enabling a computing device (which may be a personal computer, a server, a terminal device, or a network device and the like) to perform the method according to the embodiments of the present disclosure.

In an exemplary embodiment of the present disclosure, there is further provided a computer readable storage medium storing a program product capable of implementing the above method in the specification. In some possible embodiments, aspects of the present disclosure may be implemented as a form of a program product, which includes a program code. When the program product runs on the terminal device, the program code is used for enabling the terminal device to perform the steps described in the above “exemplary method” portions of this specification according to the exemplary embodiments of the present disclosure.

A program product configured to implement the above method is described according to the embodiments of the present disclosure. The program product may adopt a portable compact disc read-only memory (CD-ROM) and include a program code, and may run on a terminal device such as a personal computer. However, the program product of the present disclosure is not limited thereto. In this document, a readable storage medium may be any tangible medium that can contain or store a program for use by or in connection with an instruction execution system, apparatus, or device.

Any combination of one or more readable medium(s) may be utilized by the program product. The readable medium may be a readable signal medium or a readable storage medium. The readable storage medium may be, for example, but not limited to, an electronic, magnetic, optical, electromagnetic, infrared, or semiconductor system, apparatus, or device, or any suitable combination of the foregoing. More concrete examples (a non-exhaustive list) of the readable storage medium include the following: an electrical connection having one or more wires, a portable diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

A computer readable signal medium may include a propagated data signal with readable program code embodied therein, for example, in baseband or as part of a carrier wave. Such a propagated data signal may take any of a variety of forms, including, but not limited to, electro-magnetic, optical, or any suitable combination thereof. A readable signal medium may be any readable medium that is not a readable storage medium and that can communicate, propagate, or transport a program for use by or in connection with an instruction execution system, apparatus, or device.

Program code embodied on a readable medium may be transmitted using any appropriate medium, including but not limited to wireless, wireline, optical fiber cable, RF, etc., or any suitable combination of the foregoing.

Program code for carrying out operations of the present disclosure may be written in any combination of one or more programming languages, including an object-oriented programming language such as Java, C++ or the like and conventional procedural programming languages, such as the “C” programming language or similar programming languages. The program code may execute entirely on the user's computing device, partly on the user's computing device, as a stand-alone software package, partly on the user's computing device and partly on a remote computing device or entirely on the remote computing device or server. In a scenario involved with a remote computing device, the remote computing device may be coupled to the user's computing device through any type of network, including a local area network (LAN) or a wide area network (WAN), or may be coupled to an external computing device (for example, through the Internet using an Internet Service Provider).

Moreover, the above accompanying drawings are merely illustrative description of processes included in the method according to the exemplary embodiments of the present disclosure and are not intended to limit the present disclosure. It is easy to understand that the processes shown in the above accompanying drawings do not indicate or limit time sequences of these processes. Furthermore, it is also easy to understand that these processes may be executed, for example, synchronously or asynchronously in a plurality of circuits.

Other embodiments of the present disclosure will be apparent to those skilled in the art from consideration of the specification and practice of the present disclosure disclosed here. This application is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the following claims.

It will be appreciated that the present disclosure is not limited to the exact construction that has been described above and illustrated in the accompanying drawings, and that various modifications and changes may be made without departing from the scope thereof. It is intended that the scope of the present disclosure only be limited by the appended claims.

Other embodiments of the present disclosure will be apparent to those skilled in the art from consideration of the specification and practice of the present disclosure disclosed here. This application is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the following claims.

It will be appreciated that the present disclosure is not limited to the exact construction that has been described above and illustrated in the accompanying drawings, and that various modifications and changes may be made without departing from the scope thereof. It is intended that the scope of the present disclosure is only limited by the appended claims.

What is claimed is:

1. A fuse blowing method for a memory, comprising:
providing a programmable device; and
executing the memory by means of the programmable device by:
controlling the memory to enter a test mode, and reducing an internal clock frequency of the memory;
starting a fuse blowing load mode, and controlling the memory to enter a fuse blowing mode;
enabling internal precharge of the memory, and writing a location of a fuse to be blown into a fuse blowing location register;
starting a fuse blowing process of the memory, and disabling the internal precharge after preset time; and
controlling the memory to exit the fuse blowing mode and the test mode successively.

2. The fuse blowing method according to claim 1, wherein the controlling the memory to enter a test mode comprises:
consecutively writing three different first preset data into a test mode register in sequence, to control the memory to enter the test mode.

3. The fuse blowing method according to claim 2, wherein the consecutively writing three different first preset data into a test mode register in sequence comprises:
sending address data of the test mode register and the three different first preset data to the memory by means of a first mode register write command.

4. The fuse blowing method according to claim 1, wherein the reducing an internal clock frequency of the memory comprises:
setting a first preset bit of a clock frequency register to 1 and then to 0 by means of the first mode register write command, to reduce the internal clock frequency.

5. The fuse blowing method according to claim 1, wherein the starting a fuse blowing load mode comprises:
consecutively writing two different second preset data into a fuse blowing load register, to control the memory to start the fuse blowing load mode.

6. The fuse blowing method according to claim 5, wherein the consecutively writing two different second preset data into a fuse blowing load register comprises:
sending address data of the fuse blowing load register and the two different second preset data to the memory by means of a first mode register write command.

7. The fuse blowing method according to claim 1, wherein the controlling the memory to enter a fuse blowing mode comprises:
writing third preset data into a first fuse blowing register, to control the memory to enter the fuse blowing mode.

8. The fuse blowing method according to claim 7, wherein the writing third preset data into a first fuse blowing register comprises:
sending the third preset data to the memory by means of a second mode register write command.

9. The fuse blowing method according to claim 1, wherein the enabling internal precharge of the memory comprises:
setting a second preset bit of a second fuse blowing register to 0 and then to 1 by means of a second mode register write command, to enable the internal precharge.

10. The fuse blowing method according to claim 1, wherein the writing a location of a fuse to be blown into a fuse blowing location register comprises:
writing a coordinate value corresponding to the location of the fuse to be blown into the fuse blowing location register by means of a second mode register write command.

11. The fuse blowing method according to claim 1, wherein the starting a fuse blowing process of the memory comprises:
setting all third preset bits of a fuse blowing start register to 1 and then to 0 by means of a second mode register write command, to start the fuse blowing process.

12. The fuse blowing method according to claim 9, wherein the disabling the internal precharge after preset time comprises:
after the preset time, writing 0 into the second fuse blowing register by means of the second mode register write command, to disable the internal precharge.

13. The fuse blowing method according to claim 7, wherein the controlling the memory to exit the fuse blowing mode comprises:
writing 0 into the first fuse blowing register by means of the second mode register write command, to control the memory to exit the fuse blowing mode.

14. The fuse blowing method according to claim 2, wherein the controlling the memory to exit the test mode comprises:
writing fourth preset data into the test mode register by means of the first mode register write command, to control the memory to exit the test mode.

15. The fuse blowing method according to claim 1, wherein the programmable device is connected to a CA pin, a CKE pin, a CS pin, a CLK pin and a DQ pin of the memory.

16. A fuse blowing apparatus for a memory, comprising:
a programmable device, comprising:
a first control circuit configured to control the memory to enter a test mode, and reduce an internal clock frequency of the memory;
a second control circuit configured to start a fuse blowing load mode, and control the memory to enter a fuse blowing mode;
a third control circuit configured to enable internal precharge of the memory, and write a location of a fuse to be blown into a fuse blowing location register;
a fourth control circuit configured to start a fuse blowing process of the memory, and disable the internal precharge after preset time; and
a fifth control circuit configured to control the memory to exit the fuse blowing mode and the test mode successively.

17. A non-transitory computer-readable storage medium storing a computer program thereon, the computer program is executable by a processor to implement the fuse blowing method for a memory according to claim 1.

18. An electronic device comprising:
a processor, and
a memory configured to store one or more programs, the one or more programs are executable by the processor to implement a fuse blowing method for a memory;
wherein the method comprises:
providing a programmable device; and
executing the memory by means of the programmable device by:
controlling the memory to enter a test mode, and reducing an internal clock frequency of the memory;
starting a fuse blowing load mode, and controlling the memory to enter a fuse blowing mode;
enabling internal precharge of the memory, and writing a location of a fuse to be blown into a fuse blowing location register;
starting a fuse blowing process of the memory, and disabling the internal precharge after preset time; and
controlling the memory to exit the fuse blowing mode and the test mode successively.
